(19) United States
(12) Patent Application Publication
(10) Pub. No.: US 2025/0205961 A1
(43) Pub. Date: Jun. 26, 2025

(54) FORMABLE AND FLEXIBLE HAPTICS MATERIALS AND STRUCTURES

(71) Applicant: Alpha Assembly Solutions Inc., Waterbury, CT (US)

(72) Inventors: Niveditha NAGARAJAN, Waterbury, CT (US); Qingliu WU, Waterbury, CT (US); Ranjit PANDHER, Waterbury, CT (US); Bawa SINGH, Waterbury, CT (US)

(21) Appl. No.: 18/848,413

(22) PCT Filed: Mar. 23, 2023
(86) PCT No.: PCT/EP2023/025128

§ 371 Date: Sep. 18, 2024

Related U.S. Application Data
(60) Provisional application No. 63/322,846, filed on Mar. 23, 2022.

(51) Int. Cl. B29C 51/02; B29C 45/00; B29K 27/00; B29K 33/00; B29K 63/00; B29K 67/00; B29K 75/00; B29K 105/00; B29K 105/24; B29L 31/34; H03K 17/96; H10N 30/092; H10N 30/85

(52) U.S. Cl. CPC B29C 51/02; B29C 45/0001; H10N 30/092; H10N 30/852; B29C 2945/76531; B29K 2027/16; B29K 2033/08; B29K 2063/00; B29K 2067/00; B29K 2075/00; B29K 2105/0088; B29K 2105/24; B29K 2995/0003; B29L 2031/345; H03K 17/962

(57) ABSTRACT

A composition comprising: a piezoelectric polymer, and a binder. The composition may be printed to form a haptic component during a method of forming an electronic device.

The present invention relates to a composition, a method of manufacturing the composition, a method of manufacturing an in-mould electronic (IME) component, an in-mould electronic (IME) component, a capacitive touch switch, a resistive touch switch, a method of forming a haptic component and a haptic component.

In printed electronics, most Human-Machine Interface (HMI) electronic circuits, structures and surfaces are usually produced by screen printing conductive and dielectric inks on thin flexible substrates. Many of these circuits/structures involve resistive or capacitive touch switches. An issue with some of those touch switches is a lack of a human “feel sense” for the user. In many applications, it is often a user preference to have a feel response or some other feedback to the user's actions, while in other cases it is often necessary to get some kind of feedback to make sure that the right action has been performed. For example, in an in-mold electronic device such as being used on an automobile dashboard, a user should be able to receive non-visual feedback while turning knobs in a dark cabin. Membrane touch switch-based devices usually provide passive feedback (finger depression of a metallic dome which by an audible click) that depends on the touch senses of human fingers just as physical knobs depend on the touch and linear or rotary movement sensed by the human hand. For capacitive touch switches, passive feedback can be introduced into the design of the physical shape of the touch location (protrusion or depression) to make sure the user has touched the right location. However, to ensure that the switch, when activated, has performed its function, for example turned something on or off, another form of confirmation is needed. That feedback could be in the form of an audible signal or a low intensity vibration which can be easily sensed by human fingers (a so-called “haptic feedback mechanism”). The audio signal can be produced using a speaker built using one of the existing technologies, such as an induction coil or a piezoelectric transducer, while low intensity vibration could be generated, for example, by an electric motor. Both techniques involve use of an additional standalone rigid device, adding complexity, weight and size.

There is a need to produce a haptic component by similar printing technology that will be used to make the whole device fully functional, including the haptic feedback mechanism, without compromising any other attributes.

The present invention aims to solve at least some of the problems associated with the prior art or to provide a commercially acceptable alternative.

In a first aspect, the present invention provides a composition comprising:
a piezoelectric polymer, and
a binder.

Each aspect or embodiment as defined herein may be combined with any other aspect(s) or embodiment(s) unless clearly indicated to the contrary. In particular, any features indicated as being preferred or advantageous may be combined with any other feature indicated as being preferred or advantageous.

The inventors have surprisingly found that the composition may be used to form a haptic component during a printing method of forming an electronic device. Since the composition may be printed, the formation of the haptic component may be carried out using similar printing techniques used to make the other components of the device, such as resistive or capacitive touch switches. This may simplify the manufacture of the electronic device, and thereby reduce the cost. In addition, the size and weight of the electronic device may be decreased.

The composition comprises a piezoelectric polymer. The term “piezoelectric” as used herein may encompass a material in which electric charge accumulates in response to an applied mechanical stress or generates a mechanical force in response to an applied electric field. Without being bound by theory, it is considered that this property arises from electric dipole moments that develop in certain crystal structures. In materials that are piezoelectric, these dipoles can be oriented or aligned by a process known as poling, where a high voltage is applied across the material, which may be heated to facilitate dipole alignment. After poling, the ferroelectric material will also exhibit piezoelectric behavior. In the present invention, the piezoelectric nature of the polymer means that the composition can be used to form a piezoelectric transducer, which may form part of a haptic component such as a vibration or audio component in a HMI device. Such a piezoelectric transducer may be activated in response to being touched by a user of the HMI device.

Inorganic ceramic piezoelectric materials are known, such as lead zirconate. An inorganic crystalline piezoelectric material exhibits a greater piezoelectric response than other piezoelectric materials—for example, by generating more electric charge for the same amount of applied mechanical stress—and maintains its piezoelectric properties at higher temperatures than other piezoelectric materials. However, they are rigid and bulky, and require high temperature processing for an effective performance. For example, to form a piezoelectric transducer from lead zirconate, powder of lead zirconate is combined with additives such as an inert binder and fired at high temperatures, typically over 750° C., to form a solid shape. In contrast, by having a piezoelectric material in the form of a polymer, the composition of the present invention may be processed at temperatures low enough to avoid damage to typical electronic device substrates. Furthermore, the composition may have rheological properties suitable for printing, and may result in the formation of a flexible piezoelectric transducer.

The piezoelectric polymer is typically contained in the composition in the form of a powder.

The composition may be printable. For example the composition is preferably capable of undergoing screen-printing, stencil printing, gravure printing, offset printing and/or roll-to-roll printing, more preferably screen-printing. Such techniques are commonly employed when printing electronic components.

The composition comprises a binder. Typically, the piezoelectric polymer is dispersed within the binder. The piezoelectric polymer may be blended with the binder. The binder may serve to hold together (“bind”) the composition, and may help to provide the composition with desired rheological properties.

The composition is preferably for use in the manufacture of an in-mould electronic (IME) component. IME components are typically manufactured by printing electronic circuitry onto flexible substrates and then thermoforming the substrate into a desired shape within a mould. The use of a piezoelectric material in polymeric form renders the composition of the present invention flexible enough to retain its form on thermoforming.

The composition is preferably in the form of an ink. An ink may be suitable for printing and/or other dispensing techniques employed in a typical method of manufacturing an electronic device. The ink is preferably a conductive ink or a dielectric ink. Conductive and dielectric inks capable of forming haptic components may be particularly useful in the manufacture of a HMI electronic device.

The composition is preferably in the form of a paste. A paste may be suitably applied to a substrate using typical dispensing techniques employed in a method of manufacturing an electronic device. The paste is preferably a conductive paste or a dielectric paste. onductive and dielectric pastes capable of forming haptic components may be particularly useful in the manufacture of a HMI electronic device.

The piezoelectric polymer preferably comprises polyvinylidene fluoride (PVDF). PVDF has the following chemical formula:

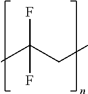

PVDF may exhibit particularly favourable piezoelectric properties and may exhibit a favourable degree of flexibility. PVDF may also be processed at temperatures low enough to avoid damage to typical substrates used in HMI devices. Without being bound by theory it is considered that in PVDF the high electronegativity of the hydrogen-flourine bond is responsible for the development of piezoelectricity.

The piezoelectric polymer preferably comprises a copolymer of PVDF, more preferably polyvinylidene fluoride-trifluoroethylene copolymer (PVDF-TrFe). While the copolymer's unit structure may be less polar than that of pure PVDF, the copolymer may exhibit a higher crystallinity. This may result in a larger piezoelectric response in comparison to pure PVDF. Typically, PVDF crystallizes into a non-polar a phase. Advantageously, by co-polymerizing with trifluoroethylene, the flourine atoms in trifluroethylene inhibit the molecular structure of the polymer, and thus PVDF-TrFe may directly crystallise in the ferroelectric B phase. The mass ratio of PVDF to co-monomer may range from 30:70 to 70:30 or from 45:55 to 55:45 or from 60:40 to 70:30.

The composition preferably comprises, based on the total weight of the composition: from 5 to 95 wt. % piezoelectric polymer, preferably 15 to 70 wt. % piezoelectric polymer, more preferably from 20 to 60 wt. % piezoelectric polymer; and from 5 to 95 wt. % binder, preferably from 30 to 85 wt. % binder, more preferably from 40 to 80 wt. % binder. This may result in a particularly favourable combination of a high piezoelectric response and suitable rheological properties.

The binder preferably comprises: a thermoplastic resin comprising a hydroxyl group, a crosslinking agent, and a solvent. The term “thermoplastic resin” as used herein may encompass a plastic polymer material that becomes pliable or moldable at a certain elevated temperature and solidifies upon cooling. The use of a thermoplastic resin may ensure that the composition is suitably pliable during thermoforming but is solid in the final electronic device. The crosslinking agent may react with the hydroxyl group at elevated temperatures so as to “cure” the composition. The solvent may serve to dissolve the thermoplastic resin, cross-linking agent and any other components of the binder.

The thermoplastic resin preferably has a glass transition temperature of less than 100° C. and/or a softening point of less than 100° C. This may render the composition particularly capable of undergoing thermoforming.

The thermoplastic resin preferably comprises one or more of a polyurethane resin, a polyester resin, a polyacrylate resin, a polyvinyl ester resin, a phenoxy resin and a ketonic resin. Such resins are particularly suitable for use in the present invention and under the drying conditions of a typical IME manufacturing method react with cross-linking to provide the desired degree of cross-linking.

The thermoplastic resin preferably comprises, based on the total weight of the thermoplastic resin: from 20 to 60 wt. % polyurethane resin, preferably from 35 to 47 wt. % polyurethane resin, from 5 to 30 wt. % polyester resin, preferably from 13 to 19 wt. % polyester resin, and from 20 to 60 wt. % phenoxy resin, preferably from 34 to 51 wt. % phenoxy resin. Such ratios of components may provide the composition with particularly favourable rheological, curing and/or adhesion properties.

Preferably, the thermoplastic resin:
comprises a homo-polymer, and co-polymer and/or a ter-polymer; and/or
has a glass transition temperature of less than 100° C.; and/or
has a weight average molecular weight of from 1000 to 100000 g/mol; and/or
has a softening point of less than 100° C.; and/or
has a hydroxyl content (OH number) of greater than 20 mgKOH/g.

This may render the composition particularly capable of undergoing thermoforming. The high hydroxyl number may result in a favourably high level of cross-linking on curing.

The crosslinking agent preferably comprises one or more of a melamine resin, an amino resin, a polyamine resin, an isocyanate, and a poly-isocyanate, more preferably melamine formaldehyde, even more preferably hexamethoxymethyl melamine. Such species may favourably react with the hydroxyl group of the thermoplastic resin, thereby resulting in a favourably high degree of cross-linking.

The cross-linking agent preferably further comprises isocyanate and/or polyisocyantate and/or blocked polyisocyanate. This may increase the level of cross-linking.

The solvent preferably comprises of one or more of an alcohol, a glycol, a glycol ether, a glycol ester, an ester, a ketone, and a hydrocarbon. Such species may be particularly suitable for dissolving the components of the binder and may provide the composition with desirable rheological properties.

The solvent preferably comprises, based on the total weight of the solvent: up to 95 wt. % glycol ether acetate, preferably up to 85 wt. % glycol ether acetate, and/or up to 95 wt. % glycol ether, preferably up to 85 wt. % glycol ether, and/or up to 15% ester, preferably up to 5 wt. % ester, and/or up to 40 wt. % ketone, preferably up to 32 wt. % ketone, and/or up to 80 wt. % alcohol, preferably up to 70 wt. % alcohol, and/or up to 30 wt. % hydrocarbon, preferably up to 22 wt. % hydrocarbon. Such ratios may render the solvent particularly suitable for dissolving the components of the binder and may provide the composition with desirable rheological properties.

The binder preferably comprises, based on the total weight of the binder: from 10 to 40 wt. % of the thermoplastic resin, preferably from 11 to 30.4 wt. % of the thermoplastic resin; from 0.5 to 12 wt. % of the crosslinking agent, preferably from 1.5 to 7.7 wt. % of the crosslinking agent; and from 40 to 85 wt. % solvent, preferably from 46.7 to 78.8 wt. % solvent.

The binder preferably further comprises a thermosetting resin, more preferably comprising one or both of acrylic resin and epoxy resin; and a curing catalyst for curing the thermosetting resin, preferably for thermally curing the thermosetting resin and/or for UV curing the thermosetting resin. The presence of the thermosetting resin and curing catalyst may serve to form a three-dimensional thermoset network. This may be beneficial when the dried composition is required to have more “thermoset” properties.

The binder preferably further comprises one or more functional additives, preferably selected from one or more of surfactants, rheology modifiers, dispersants, de-foamers, de-tackifiers, slip additives, anti-sag agents, levelling agents, surface active agents, surface tension reducing agents, adhesion promoters, anti-skinning agents, matting agents, coloring agents, dyes, pigments and wetting agents.

The binder preferably comprises, based on the total weight of the binder: from 0.5 to 12 wt. % of the cross-linking agent, preferably from 1.5 to 7.7 wt. % of the cross-linking agent; from 10 to 40 wt. % of the thermoplastic resin, preferably from 11 to 30.4 wt. % of the thermoplastic resin; and from 40 to 85 wt. % solvent, preferably from 46.7 to 78.8 wt. % solvent, optionally: from 0.1 to 30 wt. % thermosetting resin and from 0.1 to 3 wt. % curing catalyst for curing the thermosetting resin, preferably from 1 to 10 wt. % thermosetting resin and from 0.1 to 1 wt. % curing catalyst for curing the thermosetting resin; and/or from 0.1 to 20 wt. % functional additives, preferably from 1.7 to 17 wt. % functional additives.

In a further aspect, the present invention provides a method of manufacturing the composition described herein, the method comprising:
providing a solvent,
providing a thermoplastic resin having a hydroxyl group,
dissolving the thermoplastic resin in the solvent at a temperature of from 50 to 100° C., preferably from 70 to 100° C.,
cooling the solution to room temperature,
adding to the cooled solution a piezoelectric polymer, a crosslinking agent and optionally one or more of functional additives, thermosetting resins, curing catalysts for curing the thermosetting resins, conductive particles and non-conductive particles.

The advantages and preferable features of the first aspect apply equally to this aspect.

Dissolving the thermoplastic resin in the solvent at the elevated temperature may promote dissolution of the thermoplastic resin.

In a further aspect, the present invention provides a method of manufacturing an in-mould electronic (IME) component, the method comprising:
preparing a blank; and
thermoforming the blank,
   wherein preparing the blank comprises forming one or more structures on a thermoformable substrate, each structure formed by a method comprising:
disposing the composition described herein on a thermoformable substrate, and
drying the composition at a temperature of from 20 to 150° C. for from 0.5 to 60 minutes.

The advantages and preferable features of the first aspect apply equally to this aspect.

The term “thermoforming” as used herein may encompass a manufacturing process where a plastic sheet is heated to a pliable forming temperature, formed to a specific shape in a mold, and trimmed to create a usable product. The sheet is typically heated in an oven to a high-enough temperature that permits it to be stretched into or onto a mold and cooled to a finished shape. Its simplified version is vacuum forming. A pressure may be applied during the thermoforming. The thermoforming may comprise high-pressure thermoforming.

Drying the composition may comprise evaporating solvent from the composition. Typically the majority of the solvent is removed from the composition, more typically substantially all of the solvent is removed from the composition.

The one or more structures preferably comprises a multilayer stack.

The composition is preferably subjected to an electric field. This may align the majority of dipoles in the polymer chains, thereby rendering the polymer piezoelectric. The composition may be subjected to the electric field before being disposed on the substrate, after being disposed on the substrate but before being thermoformed, or after being thermoformed. The composition is preferably subjected to the electric field at elevated temperatures. This may encourage the aligning of dipoles.

The method preferably further comprises disposing one or more conductive or dielectric inks on the thermoformable substrate before disposing the composition described herein on the thermoformable substrate. In such a case, disposing the composition described herein on the thermoformable substrate comprises disposing the composition on the one or more conductive or dielectric inks disposed on the thermoformable substrate. The method may preferably further comprise, thereafter, disposing one or more conductive or dielectric inks on the composition. Accordingly, the blank may comprise a thermoformable substrate having thereon a layer of the composition sandwiched between one or more layers of conductive and/or dielectric ink. This may result in a haptic component being integrated with a capacitive or resistive touch switch.

The one or more structures preferably comprises a haptic structure, more preferably an audio speaker or mechanical vibration device.

Disposing the composition preferably comprises printing the composition, more preferably screen-printing, stencil printing, gravure printing, offset printing and/or roll-to-roll printing the composition, even more preferably screen-printing the composition.

The substrate preferably comprises one or more of polyethylene terephthalate (PET), polycarbonate (PC), paper, polymethylmethacrylate) (PMMA), polyethylene nephalate (PEN), polyimide (PI) and thermoplastic polyurethane (TPU). The composition as described herein may be compatible with, and forms strong adhesion with, such materials. Such materials also exhibit favourable thermoforming properties.

The thermoforming is preferably carried out at a temperature of from 140° C. to 210° C. Such conditions may result in particularly favourable thermoforming without causing damage to the substrate and/or degradation to the components of the composition. Such a temperature is particularly suitable for thermoforming, and the composition described herein may be stable at such a temperature. The thermoforming may comprise vacuum thermoforming. In a preferred embodiment, the vacuum thermoforming is carried out at a pressure of from 0.25 MPa to 0.4 MPa. In another preferred embodiment, the high-pressure thermoforming is carried out at a pressure of from at a pressure ranging from 6 MPa to 12 MPa.

The method preferably further comprises, after thermoforming, applying a layer of resin to the substrate using injection moulding, preferably wherein the resin comprises one or more of polycarbonate (PC), polyethylene terephthalate (PET), acrylonitrile butadiene styrene (ABS), polypropylene (PP), polyester, poly(methyl methacrylate) (PMMA), low density polyethylene (LDPE), high-density polyethylene (HDPE), polystyrene (PS) and thermoplastic polyurethane (TPU). Other similar resins may also be used. Such a layer of resin may provide the final IME component with favourable mechanical and/or aesthetic properties.

The injection moulding is preferably carried out at a temperature of from 170 to 330° C. Such a temperature is particularly suitable for injection moulding, and the composition described herein may be stable at such a temperature.

Preparing the blank preferably further comprises forming one or more conductive layers and/or dielectric layers on the substrate and/or structure.

The in-mould electronic (IME) component preferably comprises a capacitive touch switch, a resistive touch switch or a capacitive touch sensor.

The in-mould electronic (IME) component preferably comprises one or more of a display, a light/lamp, a sensor, an indicator and a haptic/touch feedback device.

In a further aspect, the present invention provides an in-mould electronic (IME) component manufactured according to the method described herein.

The advantages and preferable features of the first aspect apply equally to this aspect.

In a further aspect, the present invention provides an in-mould electronic (IME) component comprising the composition described herein.

The advantages and preferable features of the first aspect apply equally to this aspect.

In a further aspect, the present invention provides an in-mould electronic (IME) component comprising a piezolelectric polymer.

The advantages and preferable features of the first aspect apply equally to this aspect.

The in-mould electronic (IME) component of the last three aspects preferably comprises a haptic component.

In a further aspect, the present invention provides a capacitive touch switch or resistive touch switch comprising the in-mould electronic (IME) component described herein.

The advantages and preferable features of the first aspect apply equally to this aspect.

The haptic component is preferably sandwiched between two electrodes, more preferably wherein one of the electrodes comprises a touch pad.

The haptic component is preferably dielectric.

The capacitive touch preferably further comprises a dielectric layer situated between the haptic component and each electrode.

In a further aspect, the present invention provides a method of forming a haptic component, the method comprising:
providing a substrate;
disposing the composition described herein on the substrate; and
drying the composition at a temperature of from 20 to 150° C. for from 0.5 to 60 minutes.

The advantages and preferable features of the first aspect apply equally to this aspect.

In a further aspect, the present invention provides a haptic component formed using the method described herein or comprising the composition described herein.

The advantages and preferable features of the first aspect apply equally to this aspect.

The invention will now be further described with reference to the following drawings in which:

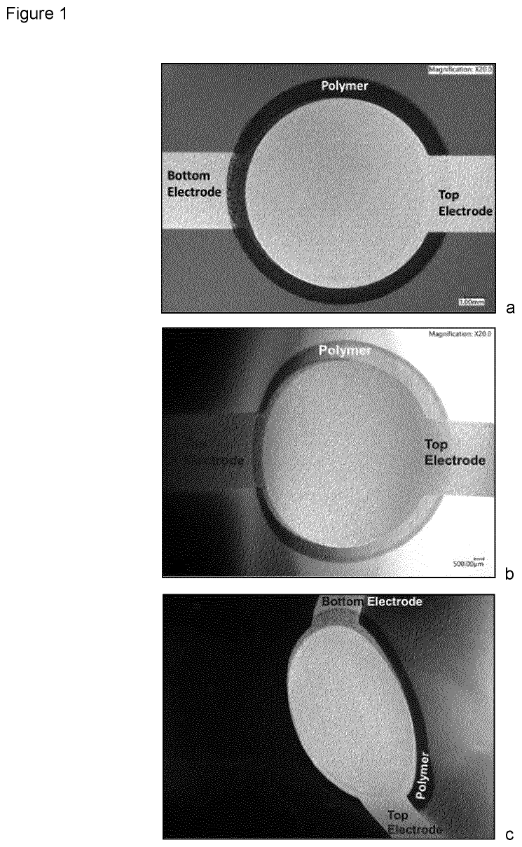

FIGS. 1a, 1b and 1c are photographs of a touch pad formed using the composition of the present invention.

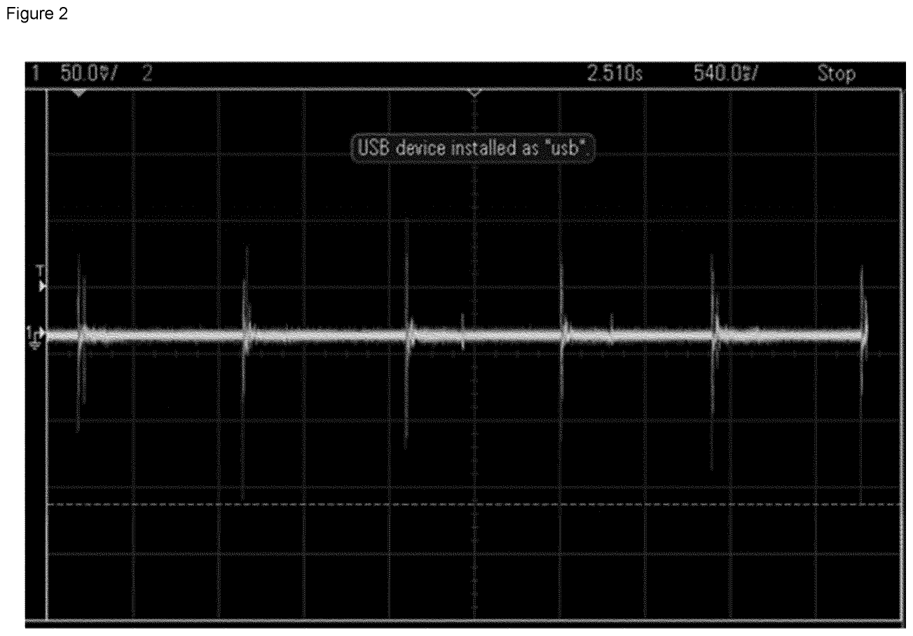

FIG. 2 shows the electrical response displayed on an oscilloscope screen when the touch pad of FIG. 1a was repeatedly pressed with a finger.

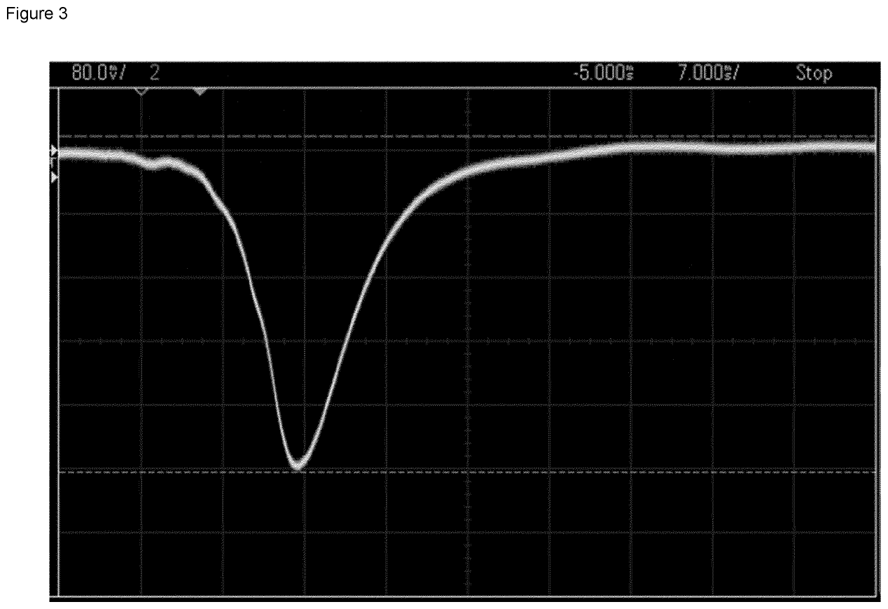

FIG. 3 shows oscilloscope screen shots of the force sense signal from a polymer based haptic integrated with capacitive touch switch.

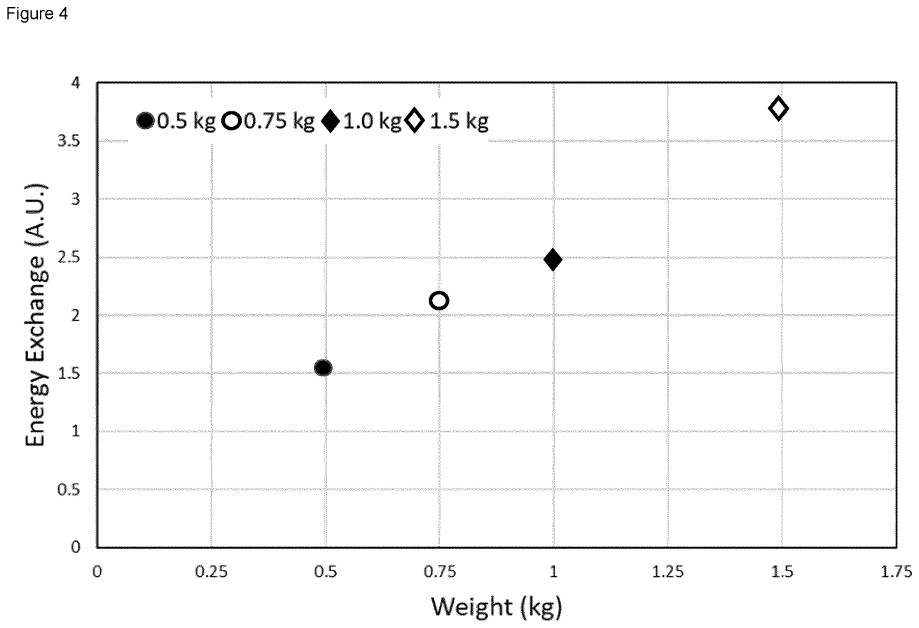

FIG. 4 shows the detected force signal from a printed touch sensor.

The invention will now be further described with reference to the following example.

### EXAMPLE

A two-electrode touch pad was prepared according to the following method. First a flexible polycarbonate film was provided. Onto the film was printed a conductive silver ink to form a bottom electrode. A composition according to the present invention in the form of an ink was then printed onto the bottom electrode to form a haptic layer, and onto the haptic layer was printed a conductive silver ink to form a top electrode. The inks were then cured in an over at a temperature of less than 120° C. The resulting touch pad is shown in FIG. 1a.

Two more two-electrode touch pads were prepared using a similar method. However, following curing, the touch pads were thermoformed at a temperature of from 150 to 180° C. The resulting thermoformed touch pads are shown in FIGS. 1b and 1c.

The touch pad of FIG. 1a was connected to an oscilloscope to monitor the electrical signal generated during experiments. During initial experiments, the central pad was repeatedly pressed with a finger to see if any electrical signal generated. To avoid grounding by the human body, an electrically insulating tape was pasted on top of the top electrode.

FIG. 2 shows the electrical response displayed on the oscilloscope screen when the touch pad was repeatedly pressed with a finger. No filter circuit was used between the touch pads and the oscilloscope. Therefore, multiple peaks are observed for each touch showing a natural response and natural damped vibrations as expected. The touch pads formed into 3D shapes (FIGS. 1b and 1c) also show performance similar to the flat sample (FIG. 1a). Extreme forming, where samples are stretched beyond the limits of the materials used to make them, may lead to degradation of performance or failure. Failure, for example, in conductive inks may be loss of conductivity while that in dielectric or haptics layer may be an increase in leakage current (loss of isolation).

FIG. 3 shows a typical electrical response from an active haptics layer under a capacitive touch pad manufactured in accordance with the present invention. In this case a known weight was placed on the touch pad. A response was recorded when the weight was quickly lifted. A variation in the response time was observed, as expected, because the weight is lifted manually. A similar response is observed when the weight is placed onto the sample. Manual nature of experiments means a variation in the applied stimulus rate/time, and hence, in observed response time. Polarity of the electrical signal is immaterial here because it depends on the order of the probe terminals.

FIG. 4 shows the total energy response of the haptics/sensor shown in FIG. 1a versus the applied force. The total energy response is calculated as the full integrated area under the response curve shown in FIG. 3. Taking this integration removes variation induced because of the manual experiment. Each data point is an average of a large number of measurements. Experiments done with different samples produce a similar response. The response signal increases with increasing applied force. This demonstrates that this structure can be used as force sensor. Alternately, the touch sensor switch can be used to turn on an electrical voltage and thus physically expand or contract the active haptics layer. An alternating voltage signal can be used to vibrate the stack at a preset frequency and send a sensory signal back to the object touching the pad.

The foregoing detailed description has been provided by way of explanation and illustration, and is not intended to limit the scope of the appended claims. Many variations in the presently preferred embodiments illustrated herein will be apparent to one of ordinary skill in the art and remain within the scope of the appended claims and their equivalents.

1-23. (canceled)

24. A method of manufacturing an in-mould electronic (IME) component, the method comprising:
preparing a blank; and
thermoforming the blank,
wherein preparing the blank comprises forming one or more structures on a thermoformable substrate, each structure formed by a method comprising:
disposing a composition on a thermoformable substrate, and
drying the composition at a temperature of from 20 to 150° C. for from 0.5 to 60 minutes,
wherein the composition comprises:
a piezoelectric polymer, and
a binder.

25. The method of claim 24, wherein the one or more structures comprises a haptic structure, preferably an audio speaker or mechanical vibration device.

26. (canceled)

27. The method of claim 24, wherein the substrate comprises one or more of PolyEthylene Terephthalate (PET), Poly-Carbonate (PC), Paper, Poly(methyl methacrylate) (PMMA), PolyEthylene Nephalate (PEN), Polyimide (PI) and Thermoplastic polyurethane (TPU).

28. The method of claim 24, wherein the thermoforming is carried out at a temperature of from 140° C. to 210° C. and/or at a pressure of from 0.25 MPa to 0.4 Mpa and/or at a pressure ranging from 6 Mpa to 12 Mpa.

29. The method of claim 24, further comprising, after thermoforming, applying a layer of resin to the substrate using injection moulding, preferably wherein the resin comprises one or more of polycarbonate (PC), polyethylene terephthalate (PET), acrylonitrile butadiene styrene (ABS), polypropylene (PP), polyester, poly(methyl methacrylate) (PMMA), low density polyethylene (LDPE), high-density polyethylene (HDPE), polystyrene (PS) and thermoplastic polyurethane (TPU).

30. The method of claim 29, wherein the injection moulding is carried out at a temperature of from 170 to 330° C.

31. The method of claim 24, wherein preparing the blank further comprises forming one or more conductive layers and/or dielectric layers on the substrate and/or structure.

32-43. (canceled)

44. The method of claim 24, wherein the piezoelectric polymer comprises polyvinylidene fluoride (PVDF).

45. The method of claim 44, wherein the piezoelectric polymer comprises polyvinylidene fluoride-trifluoroethylene copolymer (PVDF-TrFe).

46. The method of claim 24, wherein the composition comprises, based on the total weight of the composition:
from 5 to 95 wt. % piezoelectric polymer, preferably 15 to 70 wt. % piezoelectric polymer, more preferably from 20 to 60 wt. % piezoelectric polymer; and
from 5 to 95 wt. % binder, preferably from 30 to 85 wt. % binder, more preferably from 40 to 80 wt. % binder.

47. The method of claim 24, wherein the binder comprises:
a thermoplastic resin comprising a hydroxyl group,
a crosslinking agent, and
a solvent.

48. The method of claim 47, wherein the thermoplastic resin has a glass transition temperature of less than 100° C. and/or a softening point of less than 100° C.

49. The method of claim 47, wherein the thermoplastic resin comprises one or more of a polyurethane resin, a polyester resin, a polyacrylate resin, a polyvinyl ester resin, a phenoxy resin and a ketonic resin.

50. The method of claim 49, wherein the thermoplastic resin comprises, based on the total weight of the thermoplastic resin:
from 20 to 60 wt. % polyurethane resin, preferably from 35 to 47 wt. % polyurethane resin,
from 5 to 30 wt. % polyester resin, preferably from 13 to 19 wt. % polyester resin, and
from 20 to 60 wt. % phenoxy resin, preferably from 34 to 51 wt. % phenoxy resin.

51. The method of claim 47, wherein the crosslinking agent comprises one or more of a melamine resin, an amino resin, a polyamine resin, an isocyanate, and a poly-isocyanate.

52. The method of claim 51, wherein the cross-linking agent comprises melamine formaldehyde.

53. The method of claim 52, wherein the melamine formaldehyde comprises hexamethoxymethyl melamine.

54. The method of claim 52, wherein the cross-linking agent further comprises isocyanate and/or polyisocyantate and/or blocked polyisocyanate.

55. The method of claim 47, wherein the binder comprises, based on the total weight of the binder:
from 10 to 40 wt. % of the thermoplastic resin, preferably from 11 to 30.4 wt. % of the thermoplastic resin;
from 0.5 to 12 wt. % of the crosslinking agent, preferably from 1.5 to 7.7 wt. % of the crosslinking agent; and
from 40 to 85 wt. % solvent, preferably from 46.7 to 78.8 wt. % solvent.

56. The method of claim 47, wherein the binder further comprises a thermosetting resin, preferably comprising one or both of acrylic resin and epoxy resin; and a curing catalyst for curing the thermosetting resin, preferably for thermally curing the thermosetting resin and/or for UV curing the thermosetting resin.
